(19) United States
(12) Patent Application Publication
(10) Pub. No.: US 2025/0038477 A1
(43) Pub. Date: Jan. 30, 2025

(54) ACTIVE CURRENT SHIFTING FOR LASERS TO REBALANCE LASING CURRENT DIFFERENCES

(71) Applicant: SIGNIFY HOLDING B.V., EINDHOVEN (NL)

(72) Inventors: MATTHIAS WENDT, WÜRSELEN (DE); KARNEKUMAR ARULANDU, BREDA (NL); HUGO JOHAN CORNELISSEN, ESCHAREN (NL); OLEXANDR VALENTYNOVYCH VDOVIN, MAARHEEZE (NL)

(21) Appl. No.: 18/697,048

(22) PCT Filed: Oct. 5, 2022
(86) PCT No.: PCT/EP2022/077659

§ 371 Date: Mar. 29, 2024

(30) Foreign Application Priority Data
Oct. 7, 2021 (EP) 21201364.3

(51) Int. Cl. H01S 5/0683

(52) U.S. Cl. CPC H01S 5/06835

(57) ABSTRACT

The invention relates to a laser element module comprising a first laser module comprising a first laser element and a first capacitor, wherein the first laser element is coupled in series with the first capacitor; a second laser module comprising a second laser element and a second capacitor, wherein the second laser element is coupled in series with the second capacitor, wherein the first laser module is coupled in series with the second laser module; a bias current source adapted to provide a first bias current to the first laser element and a second bias current to the second laser element; a modulation current source adapted to provide an alternating current to the first capacitor, wherein the bias current source and the modulation current source, when active, are arranged to provide a total current to the first laser element and the second laser element which is always larger than a lasing current threshold of the first laser element and a lasing current threshold of the second laser element.

### FIELD OF THE INVENTION

The invention relates to a laser element module. The invention further relates to a luminaire.

### BACKGROUND OF THE INVENTION

Laser diodes are sensitive components and need a careful driver design for powering the laser diodes even when built for a high electrical input power. As known from literature, a well sustained laser diode may have a total expected lifetime of 100,000 hours but can fail in microseconds if the drivee and mounting conditions are not perfectly tuned. In addition, short surge currents can lead to Catastrophic Optical Damage (COD). If the drive current is increased to increase the optical output power to an overcurrent level, the optical output will suddenly decrease, resulting in irreversible damage. This is caused by high output levels causing a short in the laser diode, while melting a part of the laser diode edge and forming point crystal defects.

Inherently, laser diodes are susceptible to damage. Operating frequencies may exceed 1 GHz and in addition to this, laser diodes are low voltage devices that are typically operated at 2 to 5 volts.

Nowadays, the powering, and therefore reliability, of laser diodes has improved significantly. Laser diodes have also become interesting for providing general illumination. In a light source, multiple laser elements are placed in a single housing to provide a desired total light output. The laser elements are placed in a series configuration so that a single current source can be used to power the entire light source. A drawback of this configuration is that each laser element receives the same current, while the lasing current for each laser element may differ. This will result in different light outputs for each laser element at a given drive current amplitude.

### SUMMARY OF THE INVENTION

It is an objective of the invention to provide a laser element module that overcomes the problems that occur when a series string of laser elements is used when each laser element has a different lasing current threshold.

To overcome this concern, in a first aspect of the invention, a laser element module is provided. The laser element module comprises:
a first laser module comprising a first laser element and a first capacitor, wherein the first laser element is coupled in series with the first capacitor;
a second laser module comprising a second laser element and a second capacitor, wherein the second laser element is coupled in series with the second capacitor, wherein the first laser module is coupled in series with the second laser module;
a bias current source adapted to provide a first bias current to the first laser element and a second bias current to the second laser element;
a modulation current source adapted to provide an alternating current to the first capacitor,
wherein the bias current source and the modulation current source, when active, are arranged to provide a total current to the first laser element and the second laser element which is larger than a lasing current of the first laser element and a lasing current of the second laser element.

In this example, the first and second laser elements are coupled in series and are powered with two types of current sources. A bias current source is used to provide a bias current to the first and second laser elements and a modulation current source is adapted to provide an alternating current to the first and second laser module. The sum of the bias current and the alternating current are of such magnitude that they exceed the lasing current. Preferably, the sum of the bias current and the alternating current are of such magnitude that they always exceed the lasing current during operation of the laser element module. By never dropping the current through the first and second laser elements, the laser elements will remain lasing, allowing the laser elements to operate in its most efficient mode and also allowing faster modulation to be performed in the light output because the laser elements do not have to go into lasing first. Additionally, all laser elements can be provided with a single modulation current, allowing each laser element to output the same modulated light.

In a further example, the bias current source comprises:
a first shunt switch coupled in parallel with the first laser element,
a second shunt switch coupled in parallel with the second laser element,
a current source adapted to provide a constant current to the first laser element and the first shunt switch and the second laser element and the second shunt switch,
wherein the first shunt switch is adapted to shunt a part of the constant current from the first laser element such that a current through the first laser element, during operation, never drops below a lasing current threshold of the first laser element, and
wherein the second shunt switch is adapted to shunt a part of the constant current from the second laser element such that a current through the second laser element, during operation, never drops below a lasing current threshold of the second laser element.

In this example, a preferred example of the bias current source is described in more details. The bias current source has a first shunt switch, which is coupled in parallel with the first laser element. The bias current source also has a second shunt switch, which is coupled in parallel with the second laser element. A current source is used to provide a constant current to the combination of the first laser element, the first shunt switch, the second laser element and the second shunt switch. Preferably, the current source provides a current that is larger than the lasing current threshold of the first laser element and the lasing current threshold of the second laser element. The first shunt switch shunts a part of the constant current from the first laser element such that a current through the first laser element, during operation, never drops below a lasing current threshold of the first laser element. The second shunt switch shunts a part of the constant current from the second laser element such that a current through the second laser element, during operation, never drops below a lasing current threshold of the second laser element. The bias current source has in this example the function of preventing the current through any of the first laser element or the second laser element to drop below the lasing current of either of the respective laser elements.

In a further example, the first shunt switch and the second shunt switch are operated in a linear current control mode.

Operating the shunt switches in a linear current control mode provides an easy way of controlling the bias current providing the lasing currents for the laser elements.

In a further example, the first bias current is equal to a sum of the lasing current of the first laser element and half of a peak-to-peak current of the alternating current and wherein the second bias current is equal to a sum of the lasing current of the second laser element and half of the peak to peak current of the alternating current.

Preferably, the first bias current is equal to a sum of the lasing current of the first laser element and half of a peak-to-peak current of the alternating current.

In addition, the second bias current is equal to a sum of the lasing current of the second laser element and half of a peak-to-peak current of the alternating current.

When an alternating current is provided by the modulation current source, this alternating current has a peak-to-peak current amplitude. To avoid the current through either laser element to drop below the respective lasing current threshold, the bias currents are a sum of half the modulation current and the respective lasing current threshold amplitude.

In a further example, the bias current source is adapted to provide the first bias current to the first laser element at a first node between the first capacitor and the first laser element and wherein the bias current source is adapted to provide the second bias current to the second laser element at a second node between the second capacitor and the second laser element.

Preferably, the first bias current is provided to the first lasing element without passing through the first capacitor. The second bias current is provided to the second lasing element without passing through the second capacitor. In other words, the bias current source is directly connected to the first laser element and the second laser element.

In a further example, the modulation current source is adapted to provide the alternating current to the first laser element via the first capacitor and wherein the modulation current source is adapted to provide the alternating current to the second laser element via the second capacitor.

It is preferred that the current provided by the bias current source is independent from the current provided by the modulation current source. In the examples provided, this is done by providing one current as an alternating current and the other current as a direct current. In the examples provided, the bias current is provided as direct current and the modulation current as an alternating current. The modulation current is combined with the bias current via a first capacitor to the first laser element and via a second capacitor to the second laser element.

In a further example, the bias current source comprises:
a first diode for coupling the first shunt switch in parallel with the first laser element,
a third capacitor coupled in parallel with the first laser element,
a second diode for coupling the second shunt switch in parallel with the second laser element,
a fourth capacitor coupled in parallel with the second laser element.

In a more detailed example, the laser elements are provided with a parallel capacitor for filtering out high frequency currents in the laser elements. To prevent undesired discharging of the capacitors by the bias current source, diodes are used to couple the shunt switches to the laser elements.

In a further example, the laser element module comprises a first inductor and a second inductor,
wherein the third capacitor is coupled in parallel with the first laser element via the first inductor and wherein the fourth capacitor is coupled in parallel with the second laser element via the second inductor.

An additional inductor can be used for providing additional filtering of the current through the laser elements.

In a further example, the first shunt switch and the second shunt switch are operated with a pulse width modulated signal.

With the currently described topology of the switch, diode, inductor and capacitor coupled to the corresponding laser element, the switch can be operated in a pulse width modulated, PWM, operation.

In a further example, the modulation current source is adapted to modulate the current to the first laser element and the second laser element by controlling the frequency of the alternating current.

In a further example, the laser element module further comprises a light sensor for sensing a light output from the first laser element and for sensing a light output from the second laser element,
wherein the light sensor is adapted to generate a control signal, wherein the control signal is adapted to provide a determination of an occurrence of lasing of the first laser element and the second laser element.

The light output of each laser element can be used to determine if each laser element is lasing or not.

A light sensor is used to detect the light generated by the first laser element and the second laser element. The light sensor generates a control signal that is used by the controller to determine the lasing moments of the first and second laser elements.

In a further example, the laser element module comprises a first light sensor for sensing a light output from the first laser element and a second light sensor for sensing a light output from the second laser element,
wherein the first light sensor is adapted to generate a first control signal, wherein the first control signal is adapted to provide a determination of an occurrence of lasing of the first laser element, and
wherein the second light sensor is adapted to generate a second control signal, wherein the second control signal is adapted to provide a determination of an occurrence of lasing of the second laser element.

A first light sensor can be used to determine if the first laser element is lasing or not. A second light source can be used to determine if the second laser element is lasing or not.

In another example a luminaire comprises the laser element module and a housing for enclosing the laser element module.

### BRIEF DESCRIPTION OF THE DRAWINGS

Examples of the invention will now be described with reference to the accompanying drawings, in which:

FIG. 1 shows an example of a laser element module.

FIG. 2 shows a graph of the forward current versus the optical power of a laser element.

FIG. 3 shows a further example of a laser element module.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should also be understood that the Figures are merely schematic and are not drawn to scale. It should also be understood that the same reference numerals are used throughout the Figures to indicate the same or similar parts.

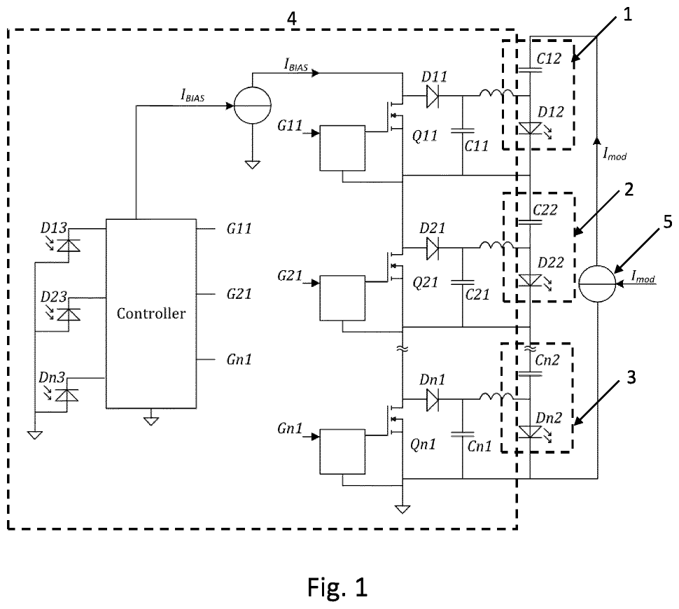

FIG. 1 shows an example of a laser element module. The laser element module allows a series connection of laser elements to emit a homogeneous light among each laser element when powered via a single current source for modulating the current through the laser elements for controlling the total light output. The laser element module uses a separate dedicated current source for providing a bias current for each laser element such that each laser element is provided with at least the required lasing current throughout the operation of the laser element module. Each laser element has a (slightly) different lasing current threshold due to tolerances of the component itself, and its junction temperature since an increasing junction temperature requires an increased lasing current. This means that each laser element requires a different bias current. The bias current source provides this tuned current to each of the laser elements so that each laser element is provided with a current that maintains all the laser elements in their lasing mode, and biases the laser elements for modulation by adding an additional DC current. As a result, each laser element will be optimally biased for modulation which improves efficiency and utilization of the total laser element power. A modulation current provided to the series connected laser elements allows each laser element to be provided with a identical current for each laser element for generating a desired light output which is approximately the same for each laser element.

In FIG. 1, the laser element module has a first laser module 1, a second laser module 2 and a third laser module 3. In this example, three laser modules are shown. It is to be understood that the laser element module can have two laser modules or more, so each example provided with three laser modules can also be used in examples where two or more laser modules are used. Each laser module is provided with a laser element and a capacitor in series with the laser element. The first laser module 1 has a first capacitor C12 coupled in series with a first laser element D12. The second laser module 2 has a second capacitor C22 coupled in series with a second laser element D22. The third laser module 3 has a third capacitor Cn2 coupled in series with a third laser element Dn2. The three laser modules are coupled in a series configuration. A modulation current source 5 is coupled to the series configuration of the laser modules. The modulation current source 5 provides an alternating current I_{mod} to the laser modules. The modulation current I_{mod} is an alternating current, which can be an alternating current, AC, current. The modulation current I_{mod} is provided to the first laser element D12 via the first capacitor C12. Because the modulation current I_{mod} is an alternating current, the first capacitor C12 is capable of passing on the current. In fact, a capacitor blocks only direct current, DC, currents. The modulation current is then further provided to the second laser element D22 via the second capacitor C22. The modulation current is then finally provided to the third laser element Dn2 via the third capacitor Cn2. Preferably, the modulation current I_{mod} may be provided by the modulation current source 5 by providing a voltage with a specific frequency to the laser modules. This voltage is applied to the impedances of the capacitors and the laser elements. The impedances of the capacitors are the most dominant impedances. The capacitors provide a frequency dependent impedance for the current that is provided by the modulation current source 5.

To each laser element, a bias current source 4 is connected. The purpose of the bias current source 4 is to provide the required current to each laser element such that the discrepancy in lasing current of each individual laser element is compensated. Preferably, the bias current source 4 provides enough current to bias the laser elements at the same optical output power level by compensating the difference in lasing current between the individual LASERs, regardless of the current provided by the modulation current. Preferably, the current provided by the bias current source 4 compensates for the mismatch in lasing current such that the common modulation current 5 can be applied through the laser elements.

The bias current source 4 may comprise a first shunt switch Q11, which is coupled in parallel with the first laser element D12. The bias current source 4 may comprise a second shunt switch Q21, which is coupled in parallel with the second laser element D22. The bias current source 4 may comprise a third shunt switch Qn1, which is coupled in parallel with the third laser element Dn2.

The bias current source 4 may have a current source. The current source may provide a bias current I_{bias} to the parallel combination of the first shunt switch Q11 with the first laser element D12, the parallel combination of the second shunt switch Q21 with the second laser element D22, and the parallel combination of the third shunt switch Qn1 with the third laser element Dn2. In this example, a single current source is used to provide a single bias current I_{bias} to all the parallel combinations. In this example, it is desired for the current source to provide a bias current I_{bias} which is larger than the largest bias current required for any of the laser elements.

In the example provided in FIG. 1, the bias current I_{bias} is provided to the first parallel combination of the first shunt switch Q11 with the first laser element D12. The first laser element D12 has a specific lasing current threshold. The current provided by the current source is larger than this specific bias current to ensure that a variation in lasing current is compensated for each individual laser element. This means that a part of the bias current I_{bias} needs to be diverted from the first laser element D12. The first shunt switch Q11 may be operated in a pulse width modulation, PWM, mode such that the excess current provided by the current source is diverted from the first laser element D12. The bias current I_{bias} is in essence divided between the biasing, current that is provided to the first laser element D12 and the excess current that is diverted via the first shunt switch Q11. These two currents are then combined again at the output of the first laser element D12, capacitor C11 and the first shunt switch Q11. This current is then provided to the second parallel combination of the second shunt switch Q21 and second laser element D22. A similar current distribution occurs as in the first parallel combination of the first shunt switch Q11 and the first laser element D12. Similar to the first and second parallel combinations, the third parallel combination of the third shunt switch Qn1 and third laser element Dn2 will be provided with a similar current distribution.

In parallel with each laser element, a capacitor can be placed to filter out high frequency components from the current through the laser elements. In parallel with the first laser element D12, a capacitor C11 may be placed. In parallel with the second laser element D22, a capacitor C21 may be placed. In parallel with the third laser element Dn2, a capacitor Cn1 may be placed. The parallel connections between capacitors and laser elements may be realized by an inductive component. This now may also allow the shunt switches to be operated with a pulse width operated control signal. Compared to a linear current regulation of the shunt switches, this may be more power efficient.

The controlling of the shunt switches can be done with a controller that provides control signals to each control gate of the corresponding shunt switch. In the example provided, each shunt switch has its own gate driver. The first shunt switch Q11 is controlled by a first gate driver, which receives a first control signal G11 from the controller. The second shunt switch Q21 is controlled by a second gate driver, which receives a second control signal G21 from the controller. The third shunt switch Qn1 is controlled by a third gate driver, which receives a third control signal Gn1 from the controller.

The control signal can be used to drive the shunt switches in the linear current regulation mode or in the PWM current regulation mode.

The lasing current threshold for each laser element can be determined in several ways. Upon assembly or in the factory, the lasing current threshold can be measured or determined.

It may be preferred to determine the lasing current threshold in the laser element module itself so that any variations of the lasing current threshold for any of the laser elements, e.g. due to aging or temperature, can be monitored and corrected for.

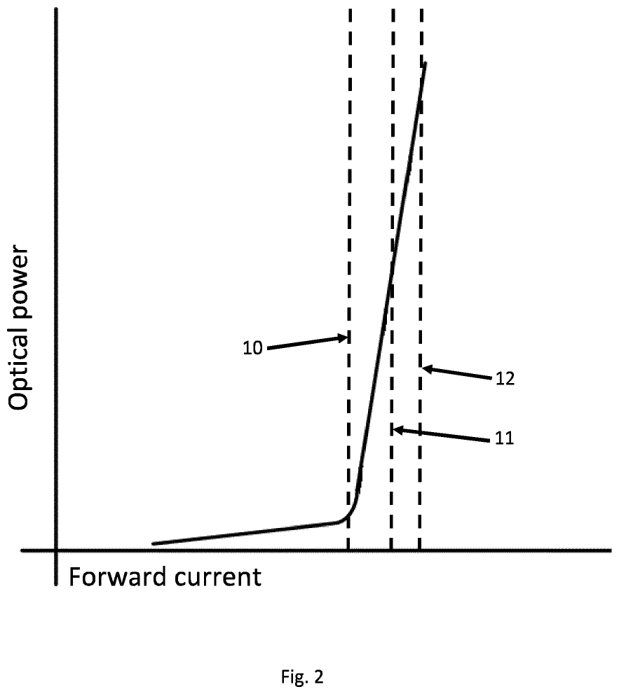

FIG. 2 shows more details of the operation of a laser element. The laser element may receive a current that allows a light to be generated. When the current is low, the laser element is not lasing but generates a very small amount of light at an extremely low efficiency. When the current is increased, the laser element will generate more light. When the lasing threshold 10 has been reached, the laser element enters the lasing mode. Light will be generated more efficiently. The lasing threshold is located in the bend of the graph at the moment where the steepness of the ratio of optical power per forward suddenly increases. Preferably, the bias current is set at a level equal to a sum of the lasing threshold 10 of the laser element and half of a peak to peak current of an alternating current or modulation current. This level is shown as the bias current threshold 11 in FIG. 2. The alternating current provided to the laser element may provide a modulation of the current in the laser element. Preferably, this current modulation takes place between the lasing threshold 10 and a maximum current 12. This modulation prevents the current to drop below the lasing threshold 10 and maintains the laser element into lasing. The threshold 12 may for example be a threshold where a safe operating of the laser element can be guaranteed e.g. a maximum operating current.

Modulation of the optical power may be used for providing data communication via light e.g. coded light and Light Fidelity, Li-Fi.

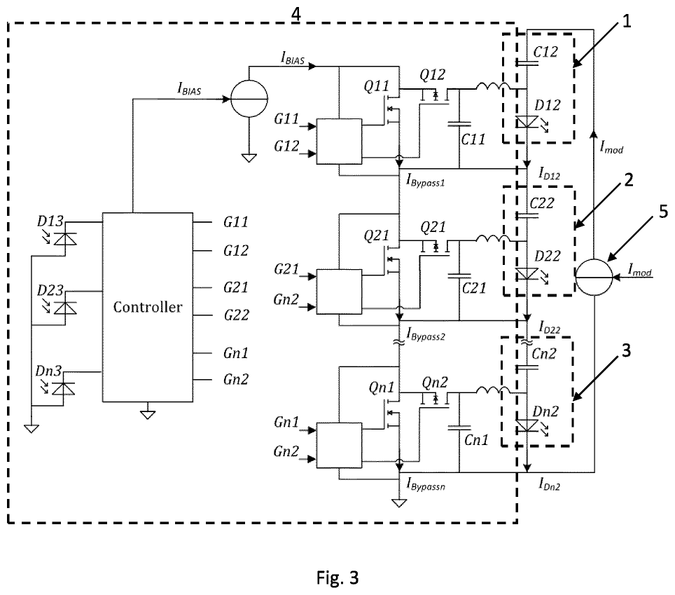

FIG. 3 shows an improved example of the laser element module as shown in FIG. 1. The main features and circuitry are similar to that of the laser element module as shown in FIG. 1 with similar reference numbers representing similar features. Similar as shown in FIG. 2, the bias current source 4 is used supply a de current higher than the highest required bias current. Additionally, the bias current source 4 is provided with an improved shunt switching circuit. The optional diodes D11, D21 and Dn1 as shown in the FIGS. 1 and 2 are now replaced with switches Q12, Q21 and Qn1, which are in this example MOSFETs. Upon conduction in the forward direction, as would happen in the case of a diode, the switch can be closed which reduces the conduction losses. This is particularly interesting when the capacitor in parallel with the laser element via the inductor.

In the examples provided, the controller is coupled to light sensors. The first light sensor D13 may be used to sense the light generated from the first laser element D12. The second light sensor D23 may be used to sense the light generated from the second laser element D22. The first light sensor D13 may be used to sense the light generated from the first laser element D12.

In the examples provided, the laser element module may have any type of laser element. A non-exhaustive list of examples of laser elements is: VCSEL (vertical-cavity surface-emitting laser), edge emitting laser diodes, interband cascade lasers, quantum cascade lasers.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A laser element module comprising:
a first laser module comprising a first laser element and a first capacitor, wherein the first laser element is coupled in series with the first capacitor;
a second laser module comprising a second laser element and a second capacitor, wherein the second laser element is coupled in series with the second capacitor, wherein the first laser module is coupled in series with the second laser module;
a bias current source adapted to provide a first bias current to the first laser element and a second bias current to the second laser element;
a modulation current source adapted to provide an alternating current to the first capacitor,
wherein the bias current source and the modulation current source, when active, are arranged to provide a total current to the first laser element and the second laser element which is always larger than a lasing current threshold of the first laser element and a lasing current threshold of the second laser element.

2. The laser element module according to claim 1, wherein the bias current source comprises:
a first shunt switch coupled in parallel with the first laser element,
a second shunt switch coupled in parallel with the second laser element,
a current source adapted to provide a constant current to the first laser element and the first shunt switch and the second laser element and the second shunt switch,
wherein the first shunt switch is adapted to shunt a part of the constant current from the first laser element such that a current through the first laser element, during operation, never drops below the lasing current threshold of the first laser element, and
wherein the second shunt switch is adapted to shunt a part of the constant current from the second laser element such that a current through the second laser element, during operation, never drops below the lasing current threshold of the second laser element.

3. The laser element module according to claim 2, wherein the first shunt switch and the second shunt switch are operated in a linear current control mode.

4. The laser element module according to claim 1, wherein the first bias current is equal to a sum of the lasing current threshold of the first laser element and half of a peak to peak current of the alternating current and wherein the second bias current is equal to a sum of the lasing current threshold of the second laser element and half of the peak to peak current of the alternating current.

5. The laser element module according to claim 1, wherein the bias current source is adapted to provide the first bias current to the first laser element at a first node between the first capacitor and the first laser element and wherein the bias current source is adapted to provide the second bias current to the second laser element at a second node between the second capacitor and the second laser element.

6. The laser element module according to claim 1, wherein the modulation current source is adapted to provide the alternating current to the first laser element via the first capacitor and wherein the modulation current source is adapted to provide the alternating current to the second laser element via the second capacitor.

7. The laser element module according to claim 2, wherein the bias current source comprises:
a first diode for coupling the first shunt switch in parallel with the first laser element;
a third capacitor coupled in parallel with the first laser element;
a second diode for coupling the second shunt switch in parallel with the second laser element; and
a fourth capacitor coupled in parallel with the second laser element.

8. The laser element module according to claim 7, further comprising a first inductor and a second inductor,
wherein the third capacitor is coupled in parallel with the first laser element via the first inductor and wherein the fourth capacitor is coupled in parallel with the second laser element via the second inductor.

9. The laser element module according to claim 8, wherein the first shunt switch and the second shunt switch are operated with a pulse width modulated signal.

10. The laser element module according to claim 1, further comprising a light sensor for sensing a light output from the first laser element and for sensing a light output from the second laser element,
wherein the light sensor is adapted to generate a control signal, wherein the control signal is adapted to provide a determination of an occurrence of lasing of the first laser element and the second laser element.

11. The laser element module according to claim 1, further comprising a first light sensor for sensing a light output from the first laser element and a second light sensor for sensing a light output from the second laser element,
wherein the first light sensor is adapted to generate a first control signal, wherein the first control signal is adapted to provide a determination of an occurrence of lasing of the first laser element, and
wherein the second light sensor is adapted to generate a second control signal, wherein the second control signal is adapted to provide a determination of an occurrence of lasing of the second laser element.

12. A luminaire comprising the laser element module according to claim 1 and a housing for enclosing the laser element module.
